(19) United States
(12) Patent Application Publication
(10) Pub. No.: US 2021/0166986 A1
(43) Pub. Date: Jun. 3, 2021

(54) PACKAGE WITH ENCAPSULANT UNDER COMPRESSIVE STRESS

(71) Applicant: Infineon Technologies AG, Neubiberg (DE)

(72) Inventors: Alexander ROTH, Zeitlarn (DE); Stefan SCHWAB, Regensburg (DE); Martin MAYER, Nittendorf (DE)

(73) Assignee: Infineon Technologies AG, Neubiberg (DE)

(21) Appl. No.: 17/101,387

(22) Filed: Nov. 23, 2020

(30) Foreign Application Priority Data
Nov. 28, 2019 (DE) 10 2019 132 314.2

(51) Int. Cl. H01L 23/31; H01L 23/29; H01L 21/56

(52) U.S. Cl. CPC H01L 23/3121; H01L 21/56; H01L 23/291

(57) ABSTRACT

A package is disclosed. In one example, the package comprises a carrier, an electronic component mounted on the carrier, an encapsulant encapsulating at least part of the carrier and at least part of the electronic component. A compression structure is provided that applies compressive stress to at least part of the encapsulant.

### CROSS-REFERENCE TO RELATED APPLICATION

This Utility patent application claims priority to German Patent Application No. 10 2019 132 314.2, filed Nov. 28, 2019, which is incorporated herein by reference.

### BACKGROUND

### Technical Field

Various embodiments relate generally to a package and a method of manufacturing a package.

### Description of the Related Art

Packages may be denoted as encapsulated electronic components with electrical connects extending out of the encapsulant. For example, packages may be connected to an electronic periphery, for instance mounted on a printed circuit board, or mounted onto a heatsink (e.g. Al or Cu) and connected via connectors to a larger system (e.g. busbars).

Packaging cost is an important driver for the industry. Related with this are performance, dimensions and reliability. The different packaging solutions are manifold and have to address the needs of a specific application.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 to FIG. 10 illustrate cross-sectional views of packages according to exemplary embodiments.

FIG. 11 illustrates a cross-sectional view of a conventional package with brittle encapsulant schematically illustrating tension caused breakage.

### DETAILED DESCRIPTION

There may be a need to provide a possibility to package an electronic component with high reliability.

According to an exemplary embodiment, a package is provided which comprises a carrier, an electronic component mounted on the carrier, an encapsulant encapsulating at least part of the carrier and at least part of the electronic component, and a compression structure configured for applying compressive stress to at least part of the encapsulant.

According to another exemplary embodiment, a method of manufacturing a package is provided, wherein the method comprises mounting an electronic component on a carrier, encapsulating at least part of the carrier and at least part of the electronic component by an encapsulant, and applying permanent compressive stress to at least part of the encapsulant (for example for counteracting tension stress).

According to an exemplary embodiment, a package is provided which can be made subject to a permanent compression force, which may be applied by a compression structure of the package. By applying the compression force, it may be possible to firmly press together the carrier, the electronic component and the encapsulant so as to prevent undesired delamination of the package. This may increase the reliability of the package.

At the same time, applying permanent compressive stress to the package may allow manufacturing the encapsulant of materials being highly temperature-stable (in particular having a better temperature stability as compared to conventional mold compounds), but being as such brittle. A brittle encapsulant may be conventionally prone to failure or damage, in particular may tend to crack, in the presence of intrinsic tension stress. It has turned out that the application of a compression force to such a brittle encapsulant may overcome the risk of an undesired formation of cracks in the encapsulant due to tension stress. Such attention stress may occur in an interior of the package, for instance due to an impact from the environment and/or due to intra-package forces. By the application of a compressive stress to the encapsulant of the package counteracting a possible tension stress, a package with high mechanical and electrical reliability as well as high thermal robustness may be provided.

In the following, further exemplary embodiments of the package and the method will be explained.

In the context of the present application, the term “package” may particularly denote an electronic device which may comprise one or more electronic components mounted on a carrier, said carrier to comprise or consist out of a single part, multiple parts joined via encapsulation or other package components, or a subassembly of carriers. Said constituents of the package may be encapsulated at least partially by an encapsulant. Optionally, one or more electrically conductive interconnect bodies (such as bond wires and/or clips) may be implemented in a package, for instance for electrically coupling the electronic component with the carrier.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating and preferably thermally conductive material surrounding at least part of an electronic component and at least part of a carrier to provide mechanical protection, electrical insulation, and optionally a contribution to heat removal during operation.

In the context of the present application, the term “carrier” may particularly denote a support structure (preferably, but not necessarily electrically conductive) which serves as a mechanical support for the one or more electronic components, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers.

In the context of the present application, the term “compression structure” may particularly denote any physical structure forming part of the package and being configured for applying a compression force to the encapsulant(s). It may also apply compression force to the electronic component and carrier being at least partially encapsulated by said encapsulant. In particular, said compression structure may be configured for applying a permanent compression force acting on the package over the entire lifetime thereof. Preferably, the applied compression force may be larger than a tension stress acting on the package, so that a net compression stress is exerted to the encapsulant (and optionally also to the electronic component and the carrier).

In the context of the present application, the term “permanent compression force” may particularly denote a not only temporary force acting on the encapsulant (and preferably also on the other constituents of the package within the encapsulant) from an exterior towards an interior of the package. For instance, such a permanent compression force may be applied by a compression structure forming part of the package or by a permanent external impact on the package. Compressive stress may denote a force that causes a material to deform to occupy a smaller volume. When a material is experiencing a compressive stress, it is said to be under compression. In one embodiment, such compressive stress may be applied over the whole package or at least over the whole encapsulant consistently. In another embodiment, however, it may be sufficient that only part of the package and in particular only part of the encapsulant is exposed to compressive stress, preferably at a location that is exposed to tensile stress, thus counteracting the tensile stress by the principle of superposition.

A gist of an exemplary embodiment is the provision of an encapsulant which may be embodied for example as a body of inorganic and/or temperature-stable mold compound (preferably as a replacement for an epoxy mold compound) which is kept under compressive stress in order to avoid stress cracks. For example, the compressive stress may be applied by a compression structure of the package provided for said purpose. The compressive stress can be generated by various measures such as grating, post-shrinking, screwing, provision of a clip with spring element, provision of an external housing, provision of expanding fillers, force-locking, etc. The encapsulant body which may be made of an inorganic and/or a temperature-stable molding compound may thus be kept under compressive stress to avoid stress cracking.

In an embodiment, the compression structure is connected with the encapsulant, in particular with direct physical contact. Thereby, a compressive stress created by the compression structure may be directly transferred to the encapsulant.

In an embodiment, the encapsulant is an inorganic encapsulant. Thus, inorganic encapsulants which may be different from conventional organic (i.e. carbon-based) mold compounds may be implemented. Such inorganic encapsulants may have the advantage of having a high temperature stability of in particular at least up to 300° C. While such inorganic encapsulants may be brittle so that an inorganic encapsulant may be prone to cracks, the provision of a compression structure or a permanent compression force may render inorganic encapsulants usable for packages according to exemplary embodiments for applications even under harsh conditions.

In an embodiment, the encapsulant may be made of a ceramic (in particular cement) or a glass material. In particular, the encapsulant may be not an organic mold compound, in particular not an epoxy based mold compound. Ceramic and class materials may be highly temperature stable. By applying a compression force to the package, the usually brittle character of ceramic or glass can be considered. Thus, the encapsulant can be a brittle encapsulant without running the risk of cracking.

In an embodiment, the compression structure comprises a compressive inlay which is at least partially arranged in an interior of the encapsulant and applies a compression force to the encapsulant. Such an inlay may be integrated in an interior of the package. Thus, the package may have an exterior appearance and exterior properties which do not differ from conventional packages, so that no modification of the application conditions needs to be considered. The interior inlay may apply the compressive stress which increases the reliability of the package.

In an embodiment, the compressive inlay is a grid. Such a grid or mesh may for instance be made of an appropriate metallic, ceramic or plastic material. Descriptively speaking, material of the encapsulant may flow into the openings of the grid during encapsulation so as to establish a proper interlocking between compression structure and encapsulant. Thus, the compression force may be properly transmitted from such a grid-based compression inlay to the encapsulant.

In an embodiment, the compression structure comprises or consists of a material having a larger coefficient of thermal expansion (CTE) than a material of the encapsulant. In particular, the compression structure may have been connected with the encapsulant in a heated condition. Correspondingly, the method may comprise connecting the compression structure, having a larger CTE value than a material of the encapsulant, with the encapsulant in a heated condition. When material of the compression structure having a higher CTE than material of the encapsulant is embedded in a heated condition into the encapsulant, subsequent cooling to operation temperature may automatically generate a compression force of the compression structure acting on the encapsulant, as a consequence of the different CTE values.

In an embodiment, the compression structure comprises a fastening element fastened to the encapsulant at an exterior of the encapsulant. Correspondingly, the method may comprise fastening a fastening element to an exterior of the encapsulant after completing the encapsulating to thereby apply the compression force to the encapsulant. For instance, such a fastening element may be a screw or a nut. Highly advantageously, fastening forces may be applied from two opposing sides onto the encapsulant for generating a specifically strong compression force. This may be accomplished for example by two or more fastening elements.

In an embodiment, the compression structure comprises a connection body having an encapsulated portion and a non-encapsulated portion. The fastening element may be fastened on the non-encapsulated portion. For instance, the mentioned connection body may be a shaft extending through the encapsulant and having inner or outer threads at least in the non-encapsulated portion(s) so that a fastening element like a screw or a nut with a corresponding thread may be simply screwed on the connection body for applying compressive stress to the encapsulant.

In an embodiment, the compression structure comprises a compression clamp, in particular a compressive clip, engaging an exterior of the encapsulant to thereby apply a compression force to the encapsulant. Thus, it may be possible to clamp a body on the encapsulant to thereby apply the compression force. A simple way of doing this is providing a spring type clamp which is clamped exteriorly over the encapsulant.

In an embodiment, the compression clamp extends into the carrier. When the clamp also extends in the carrier, a compression force may be applied not only in a clamping direction (for instance a horizontal direction) directly to the encapsulant, but additionally also in a connection direction (in particular a vertical direction) between compression clamp and carrier, resulting from the connection of the compression clamp with the carrier.

In an embodiment, the compression structure is made of a material being shrunk after being at least partially surrounded by the encapsulant and/or after at least partially surrounding the encapsulant. Correspondingly, the method may comprise surrounding the encapsulant by an exterior casing, and subsequently shrinking a material of the exterior casing. By such a post-assembly shrinking of material of the compression structure, the compression force may be created and applied after shrinking and therefore in a properly defined way.

In an embodiment, the compression structure comprises or consists of an exterior casing at least partially surrounding the encapsulant and applying a compressive force to the encapsulant. According to such a preferred embodiment, a casing surrounding at least part of the encapsulant may apply the compressive stress to the encapsulant.

In an embodiment, the exterior casing is a further encapsulant at least partially encapsulating the encapsulant. Highly preferably, the casing type compression structure may thereby be formed by overmolding the encapsulant, for instance in form of a mold compound (such as an organic mold compound, for instance an epoxy based mold compound) surrounding at least partially an inorganic encapsulant.

In an embodiment, the exterior casing has an opening smaller than a volume of the encapsulant. In such an embodiment, the encapsulant may be press fit into the opening. Correspondingly, the method may comprise press fitting the encapsulant into an opening of an exterior casing to thereby apply a compression force. In such an embodiment, the compression force may be generated by the smaller dimension of the opening of the casing type compression structure compared to the encapsulant.

In an embodiment, the exterior casing is made of a material being shrunk after at least partially surrounding the encapsulant. Shrinking the exterior casing post-assembly is a simple and efficient way of generating a compression force acting on the encapsulant in a defined way.

In an embodiment, the encapsulant and/or the compression structure comprises filler particles being expanded after at least partially surrounding the encapsulant by the casing. Correspondingly, the method may comprise surrounding the encapsulant at least partially by an exterior casing, and subsequently expanding filler particles after being surrounded by the casing. Thus, filler particles may be embedded in the material of the casing and/or in the material of the encapsulant and may be triggered thereafter to expand spatially, for instance by the application of heat and/or microwave radiation. As a result, the expanding filler particles may generate a compressing force on the encapsulant. Descriptively speaking, expansion of the filler particles may be carried out in a similar way as the production of popcorn based on grains of corn in a microwave.

In an embodiment, the method comprises at least partially surrounding the encapsulant with a casing-type compression structure having a value of the coefficient of thermal expansion (CTE) being larger than a value of the coefficient of thermal expansion of the encapsulant, and the method further comprises surrounding the encapsulant by the casing at a temperature above operation temperature of the package and subsequently operating the package at the lower operation temperature. In such an embodiment, the outer material is attached at higher temperatures and has a CTE that is larger than the one of the inner material. After attaching the material at higher temperature, the outer material will shrink stronger (due to the higher CTE) as the inner material, thus a compressive stress is applied.

In another embodiment, the method comprises at least partially surrounding the encapsulant with a casing-type compression structure having a value of the coefficient of thermal expansion (CTE) being smaller than a value of the coefficient of thermal expansion of the encapsulant, and the method further comprises surrounding the encapsulant by the casing at a temperature below operation temperature of the package and subsequently operating the package at the higher operation temperature. In said embodiment, the outer material has a lower CTE than the inner material and the outer material is attached at lower temperature (for instance at room temperature). When heating up such a device or package, the external casing will expand less than the inner material. The stronger expanding inner material will therefore cause compressive stress by pressing against the outer shell.

In an embodiment, the compression structure comprises or consists of a mold compound, in particular comprising an epoxy resin or a polymer ceramic. Thus, the compression structure may be an organic or polymer based mold compound which may apply a compression force to an inorganic encapsulant due to the different material configurations.

In the context of the present application, the term “polymer” may particularly denote a substance made of molecules being composed of a plurality of repeated subunits. Polymers may be created by polymerization of multiple smaller molecules (which may be denoted as monomers, etc.). Polymerization may denote a process of reacting monomer molecules together in a chemical reaction to form polymer chains or three-dimensional networks. A polymer may be a material which is capable of cross-linking. In the context of the present application, the term “ceramic” may particularly denote a technical ceramic. Such technical ceramics may have the properties according to ENV 12212 (in the most recent version at the priority date of the present application). In particular, the ceramic may be a highly developed, high-performance applicable ceramic material, which may be mainly non-metallic and inorganic and may have certain functional properties. In particular, the term “ceramic” in the scope of this disclosure may encompass all listed ceramic types of ENV 12212: C 111, C 112, C 120, C 130, C 140, C 210, C 221, C 221, C 230, C 240, C 250, C 410, C 420, C 430, C 440; C 510, C 511, C 512, C 520, C 530, C 610, C 620, C 310; C 320, C 330, C 331, C 340, C 350, C 351, C 780, C 786, C 795, C 799, RBAO (denoting a term according to DIN ENV 14 242), C 810, C 820, MgO (denoting a term according to DIN ENV 14 242), PSZ (denoting a term according to DIN ENV 14 242), FSZ (denoting a term according to DIN ENV 14 242), TZP (denoting a term according to DIN ENV 14 242), ATI (denoting a term according to DIN ENV 14 242), PZT (denoting a term according to DIN ENV 14 242), SiO2 (denoting a term according to DIN ENV 14 242), TiO2 (denoting a term according to DIN ENV 14 242). Also Spinel or Mullite materials, both denoting commonly used engineering terms, may be covered by the term “ceramic”. In the context of the present application, the term “polymer ceramic” may particularly denote (for instance inorganic-organic) composites comprising or consisting of ceramic fillers and a polymer, particularly polysiloxanes. The formation of polymer ceramics may be based on thermal curing of functionalized resins being able to form ceramic-like structures as a result of a heat treatment, for instance above 200° C. Relevant usage properties (for example electric insulation, thermal conductivity, coefficient of thermal expansion, hardness) and processing parameters can be adjusted by the choice of appropriate functional fillers, binder systems, and/or (for example plasticizing) additives. For instance, polymer-ceramic composites may be prepared via melt extrusion using high-density polyethylene and low-density polyethylene coated BaO—Nd₂O₃—TiO₂ ceramic-powders as the filler. The polymer material may be in particular a material which can be converted into a ceramic material at very high temperatures (for instance polysiloxane). Within the polymer, the remaining constituents of the compression structure may be mixed. In other words, the polymer may be a substance in which other constituents, in particular filler particles, can be embedded.

The polymer in an uncured state can be selectively and adjustably cured by triggering cross-linking of the polymer of the polymer ceramic. The degree of curing may be used as a design parameter for a fine adjustment of the properties of the obtained polymer ceramic, for instance in terms of its coefficient of thermal expansion. Ceramic filler particles may be a further constituent of the polymer ceramic. In particular, they can be selected specifically so that the physical properties of the compression structure can be adjusted correspondingly. For instance, the filler particles may be selected for increasing the thermal conductivity, the electrically insulating property and/or the mechanical robustness. In particular, silicon organic polymers have turned out as properly compatible with the requirements of a compression structure.

In an embodiment, the polymer (in particular a silicon organic polymer) may comprise at least one of the group consisting of polysiloxane, polycarbosilane, polysilazane, and polyborosilazane. More precisely, such materials may be used as precursor materials of the readily manufactured and cured polymer ceramic. In view of its advantageous properties for a package, polysiloxane is an advantageous option.

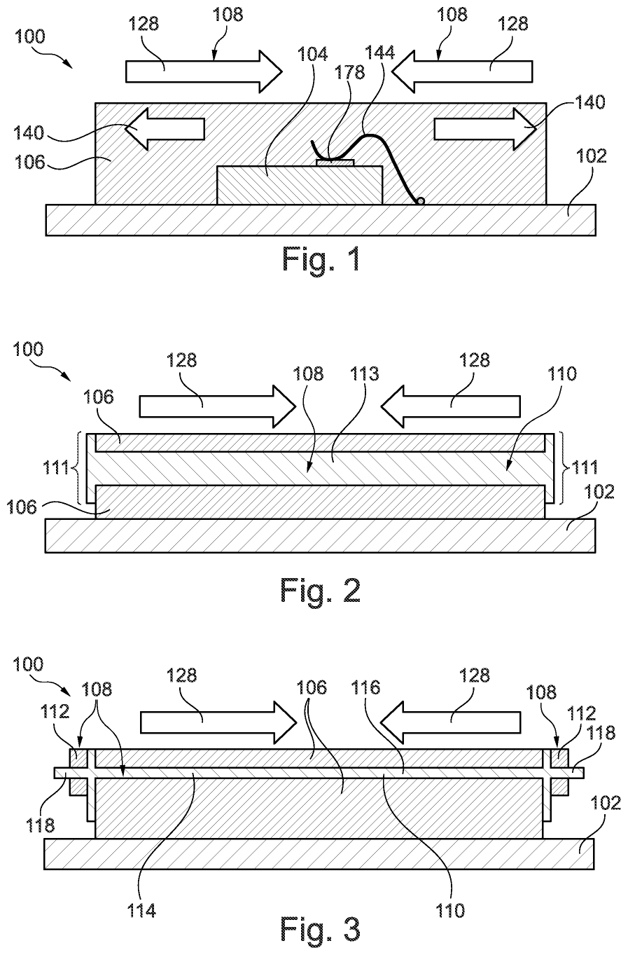

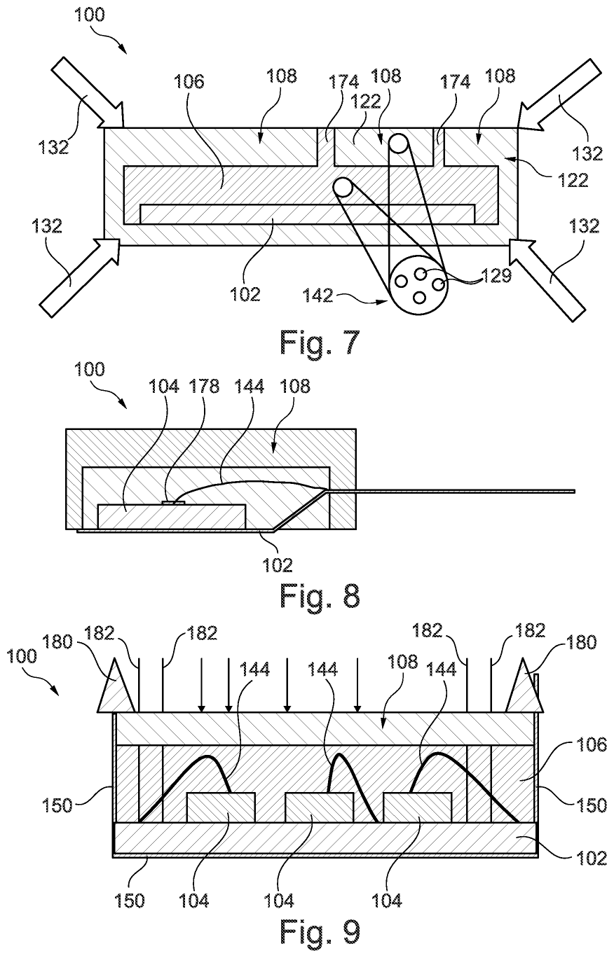

In an embodiment, the compression structure is configured for applying compressive stress to the encapsulant along two opposing (in particular horizontal) directions, along a vertical direction and/or along at least four directions being oriented inwardly, i.e. towards an interior of the package. An advantageous configuration compresses the encapsulant from at least two opposing sides (compare for instance FIG. 1). Preferable is also a compression force acting from multiple directions along the perimeter of the encapsulant inwardly (compare for instance FIG. 7).

In an embodiment, the package comprises a further carrier, wherein the electronic component is arranged between the carrier and the further carrier in such a manner that heat generated by the electronic component is removed via the carrier and the further carrier. When sandwiching the electronic component between two carriers both capable of removing heat generated during operation of the package, a double-sided cooling architecture may be provided in which the presence of the compression structure simultaneously ensures mechanical integrity of the package.

In an embodiment, the package is configured as a module, in particular comprising a plurality of encapsulated electronic components and/or comprising an exterior frame. By encapsulating preferably multiple encapsulated electronic components by a brittle, but temperature-stable encapsulant and applying a compression force by the compression structure, not only the mechanical integrity of the package as a whole may be improved, but also the adhesion at an interface between the electronic chips on the one hand and the carrier and/or the encapsulant on the other hand. Thus, a proper electric, mechanical and/or thermal reliability may be obtained.

In an embodiment, the compression structure comprises an exterior compression body, in particular an exterior compression plate, pressed onto the encapsulant. Applying compressive stress an exterior compression plate or another kind of compression body to an exterior of the encapsulant is a simple way of increasing the mechanical reliability of the package.

In an embodiment, the compression structure (108) is configured for applying a compressive stress of at least 100 N/m², in particular at least 1000 N/m², more particularly at least 10000 N/m². The mentioned values may refer to operation temperature (for instance a temperature in a range from 150° C. to 250° C.) and/or room temperature. A skilled person will understand that there may be a temperature distribution along the package. These minimum values may be appropriate for compensating tension stress to such an extent that even the use of a brittle encapsulant becomes possible without the risk of damage of the package, in particular without the risk of crack formation in the encapsulant.

In embodiment, the method comprises applying a permanent compressive stress and/or the compression structure may be configured for applying compressive stress exceeding tension stress by at least 10⁻³ N/m², in particular by at least 1 N/m², more particularly by at least 100 N/m². The mentioned differences may refer to operation temperature (for instance a temperature in a range from 150° C. to 250° C.) and/or room temperature. In particular within the above-mentioned ranges of absolutes compressive stress, it should be mentioned that any positive compressive stress consistently applied over a range of operation temperatures may be sufficient. Even 10⁻³ N/m² may be enough to achieve the effect of mechanically protecting the package and/or suppressing the delamination, as long as no tensile stress is happening to the brittle material over the operating temperature range.

In an embodiment, the carrier comprises a leadframe, in particular comprising a die pad and a plurality of leads. Such a leadframe may be a sheet-like metallic structure which can be patterned so as to form one or more die pads or mounting sections for mounting the one or more electronic components of the package, and one or more lead sections for an electric connection of the package to an electronic environment when the electronic component(s) is/are mounted on the leadframe. In an embodiment, the leadframe may be a metal plate (in particular made of copper) which may be patterned, for instance by stamping or etching. Forming the chip carrier as a leadframe is a cost-efficient and mechanically as well as electrically advantageous configuration in which a low ohmic connection of the at least one electronic component can be combined with a robust support capability of the leadframe. Furthermore, a leadframe may contribute to the thermal conductivity of the package and may remove heat generated during operation of the electronic component(s) as a result of the high thermal conductivity of the metallic (in particular copper) material of the leadframe. A leadframe may comprise for instance aluminium and/or copper.

In another embodiment, the carrier comprises a stack composed of a central electrically insulating and thermally conductive layer (such as a ceramic layer) covered on both opposing main surfaces by a respective electrically conductive layer (such as a copper layer or an aluminium layer, wherein the respective electrically conductive layer may be a continuous or a patterned layer), a Direct Copper Bonding (DCB) substrate, and a Direct Aluminium Bonding (DAB) substrate.

In an embodiment, all leads or terminals of the carrier may protrude laterally out of the encapsulant (which may correspond to a leaded package architecture). However, it is also possible that the package is a leadless package.

In an embodiment, a connection between the electronic component and the carrier is formed by a connection medium. For instance, the connection medium may be a solder structure, a sinter structure, a welding structure, and/or a glue structure. Thus, mounting the electronic component on the carrier may be accomplished by soldering, sintering or welding, or by adhering or gluing.

In an embodiment, the package comprises a plurality of electronic components mounted on the carrier. Thus, the package may comprise one or more electronic components (for instance at least one passive component, such as a capacitor, and at least one active component, such as a semiconductor chip).

In an embodiment, the at least one electronic component comprises at least one of the group consisting of a controller circuit, a driver circuit, and a power semiconductor circuit. All these circuits may be integrated into one semiconductor chip, or separately in different chips. For instance, a corresponding power semiconductor application may be realized by the chip(s), wherein integrated circuit elements of such a power semiconductor chip may comprise at least one transistor (in particular a MOSFET, metal oxide semiconductor field effect transistor), at least one diode, etc. In particular, circuits fulfilling a half-bridge function, a full-bridge function, etc., may be manufactured.

In an embodiment, the package is configured as power converter, in particular one of an AC/DC power converter and a DC/DC power converter. However, also other electronic applications, such as inverters, etc. may be possible.

As substrate or wafer for the semiconductor chips, a semiconductor substrate, i.e. a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

According to an exemplary embodiment, a package is provided in which a package body (in particular an encapsulant thereof) may be maintained under compressive stress. Such a compressive stress may be applied permanently to the encapsulant by an intrinsic and integral portion of the package itself, i.e. by a compression structure thereof.

Conventionally, discrete devices may be encapsulated using epoxy mold compounds. These organic compounds are in many cases not thermally stable beyond a temperature of 4 instance 200° C.

A solution for this shortcoming is a switch to inorganic and temperature-stable compounds like glasses, ceramic or other similar compounds. However, many of these materials are brittle and react poorly to tension by cracking. Hence, the mentioned inorganic encapsulants are advantageously stable, but unfortunately show a pronounced tendency of cracking in response to tension stress.

According to an exemplary embodiment, it may become possible to use high temperature stable encapsulant materials in a package while avoiding the described tension crack issue of said brittle encapsulant materials. By keeping the package body under compressive stress, the formation and progression of cracks in brittle materials can be inhibited. The necessary compression for can be produced by a range of structural and/or procedural measures. Descriptively speaking, a prestressed temperature stable (for instance ceramic-based) encapsulation may be provided for improving the mechanical integrity of a corresponding package. Exemplary embodiments providing such a permanent compressive stress, for instance applied by a compression structure, may be particularly advantageous for SiC (silicon carbide) devices, GaN (gallium nitride) devices, and all applications requiring a temperature increase during manufacture and/or operation.

For instance, expanding filler agents can be used in conjunction with a surrounding housing or casing. In this context, it may be advantageous that the fillers are expanded post-production (for instance by a microwave triggered expansion of organic filler particles, similar to the preparation of popcorn in a microwave oven).

Additionally or alternatively, the encapsulant body can be geometrically larger than a surrounding housing, which constitutes the compression structure. Said larger encapsulant body can then be inserted by force into the housing or casing which may produce the required compressive stress.

Encapsulation materials made of an inorganic material (for instance a ceramic) have excellent properties in terms of temperature stability, but are in many cases brittle. This makes such inorganic encapsulant materials prone to the formation of cracks and to a rapid spreading or propagation of a crack over a larger portion of the encapsulant. However, such inorganic encapsulants have turned out to be only prone to failure in the presence of tension stress, but are stable against the application of remarkably high compression forces. An exemplary embodiment thereby provides a package with such an inorganic encapsulant to which a (in particular permanent) compression force may be applied, for instance by a compression structure forming part of the package. As a result, a highly temperature-stable package may be obtained which is securely protected against mechanical failure caused by tension stress. More particularly, such an embodiment highly advantageously improves the intra-package adhesion between carrier, electronic component and encapsulant, since in particular interfaces between electronic component and encapsulant are properly held together by the applied compressive force. As a result, a highly robust package may be obtained in which any tendency of delamination may be strongly suppressed.

FIG. 1 illustrates a cross-sectional view of a package 100 according to an exemplary embodiment.

The package 100 comprises a carrier 102, such as a leadframe. An electronic component 104, for instance a semiconductor chip, is mounted on the carrier 102. A connection between a top surface of the carrier 102 and a bottom surface of the electronic component 104 may for instance be made by soldering. As shown as well, a pad 178 on an upper main surface of the electronic component 104 may be connected with the carrier 102 by a bond wire 144. Although an electronic component 104 can also be present in each of the below described embodiments of FIG. 2 to FIG. 9, an electronic component 104 is not shown in said embodiments for the sake of simplicity.

Furthermore, the package 100 comprises an encapsulant 106 which encapsulates part of the carrier 102 and the entire electronic component 104. Preferably, the encapsulant 106 is an inorganic encapsulant 106, for example may of a ceramic such as cement, or made of a glass. This material selection of the encapsulant 106 has the consequence that the encapsulant 106 is advantageously highly temperature stable. However, the mentioned materials of the encapsulant 106 are brittle and thus shows the tendency of cracking in the presence of tension forces (see reference sign 140 and FIG. 11).

In order to overcome this shortcoming, the shown embodiment applies a permanent compressive stress to the encapsulant 106 for counteracting the tension stress 140. This may advantageously protect package 100 against undesired cracking. Preferably, a net effective compressive stress being a sum of intrinsic tension stress (see reference sign 140) and applied compressive stress (see reference sign 128) may be positive.

Hence, the package 100 shown in FIG. 1 is highly temperature robust and at the same time mechanically robust. The high temperature stability may be achieved by the provision of the encapsulant 106 from an inorganic material such as a cement. The brittle character of an encapsulant 106 of such a material can be rendered mechanically robust by applying compressive stress to the encapsulant 106, see reference numeral 128. In the shown embodiment, the permanent compressive stress is applied along two antiparallel horizontal directions. Therefore, the applied compressive stress may overcompensate undesired tension (see reference numeral 140) which may conventionally result in the formation of cracks (see reference sign 210 in FIG. 11).

FIG. 2 illustrates a cross-sectional view of a package 100 according to another exemplary embodiment.

The embodiment of FIG. 2 comprises a compression structure 108 forming integral part of the package 100 and being configured for applying compressive stress to the encapsulant 106. More specifically, the illustrated compression structure 108 is configured for applying compressive stress to the encapsulant 106 along two opposing horizontal directions 128. For this purpose, the compression structure 108 comprises a compressive inlay 110 which is partially arranged in an interior of the encapsulant 106 and which is partially arranged outside of the encapsulant 106. The compressive inlay 110 applies a compression force to the encapsulant 106 by compressive plate ends 111 forming encapsulant exterior end portions of the compressive inlay 110 and engaging sidewalls of the encapsulant 106. Said plate ends 111 cooperate with an encapsulated central body 113 of the compressive inlay 110. For instance, the central body 113 of the compressive inlay 110 may be a grid or a mesh providing a proper interlocking with the encapsulant 106 to thereby efficiently transmit compressive forces.

It may be advantageous that the compression structure 108 comprises or consists of a material having a larger coefficient of thermal expansion (CTE) than a material of the encapsulant 106. When, under said circumstances, the compression structure 108 has been connected with the encapsulant 106 in a heated condition, this may generate a considerable amount of permanent compression force at a lower operating temperature. More specifically, the manufacturing method may comprise connecting the compression structure 108, having a larger CTE value than a material of the encapsulant 106, with the encapsulant 106 in a heated condition. After cooling, the compression structure 108 has contracted more than the encapsulant 106 and thereby creates the compressive force.

Summarizing, the embodiment of FIG. 2 implements a compressive inlay 110 as compression structure 108 which may be embodied as a grid or mesh or a wire with a value of the CTE being larger than the value of the CTE of the encapsulant 106 or package body. A hot assembly may finally generate the compressive stress. Additionally or alternatively, it may also be possible to carry out a post-mold-shrinkage process. In FIG. 2, the compression structure 108 is embodied as an inlay 110 which is partially integrated in the encapsulant 106 with a form closure so that a contraction force acting on the compression structure 108 will exert a compression force to the encapsulant 106.

FIG. 3 illustrates a cross-sectional view of a package 100 according to still another exemplary embodiment.

According to FIG. 3, the compression structure 108 comprises two fastening elements 112 (embodied as nuts) fastened to the encapsulant 106 at an exterior of the encapsulant 106. More specifically, the compression structure 108 comprises a connection body 114 having a central encapsulated portion 116 and a non-encapsulated portion 118 at two opposing ends of the central encapsulated portion 116. The fastening elements 112 may have internal threads and may thus be screwed on the externally threaded non-encapsulated portion 118, which may be a threaded shaft or rod. The fastening elements 112 may be fastened to an exterior of the encapsulant 106 after completing the encapsulating to thereby apply the compression force to the encapsulant 106. As a result, a post assembly tightening may be obtained.

In the embodiment of FIG. 3, the compression force is applied by tightening the nut-type (or alternatively screw-type) fastening elements 112 to press against both opposing sidewalls of the encapsulant 106. This generates a compression force acting in a horizontal direction on the encapsulant 106.

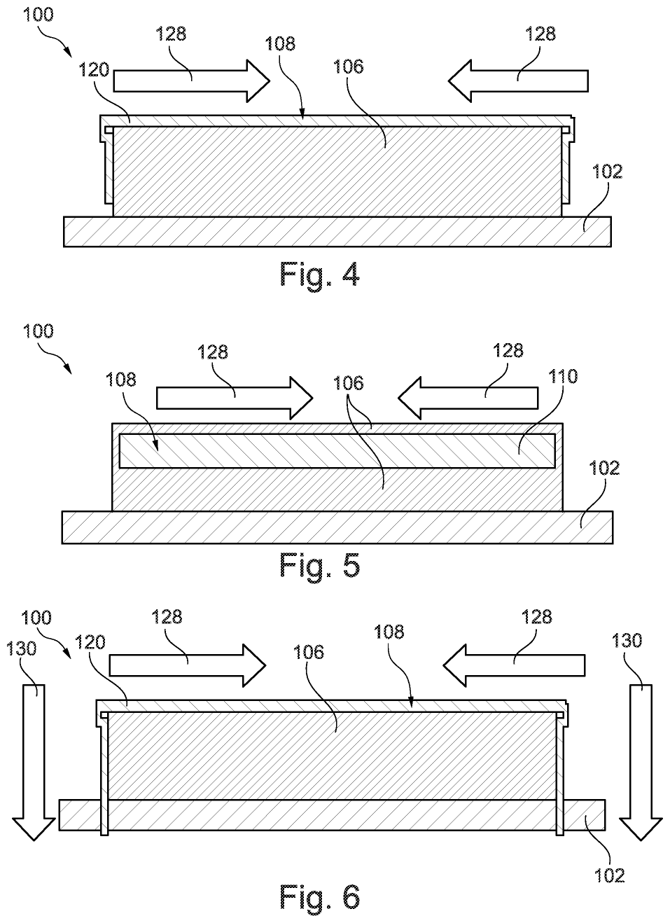

FIG. 4 illustrates a cross-sectional view of a package 100 according to yet another exemplary embodiment.

According to FIG. 4, the compression structure 108 comprises a compression clamp 120 which is here embodied as a compressive clip for engaging two opposing sidewalls of the encapsulant 106 to thereby generate a compression force exerted to the encapsulant 106. The compressive clip can be embodied for example with one more spring elements for clamping the encapsulant 106. The clamp type compression structure 108 according to FIG. 4 generates a compression force acting on two opposing sidewalls of the encapsulant 106 in an antiparallel direction.

FIG. 5 illustrates a cross-sectional view of a package 100 according to yet another exemplary embodiment. In the shown embodiment, the compression structure 108 is embodied as an inlay 110 and is made of a material being shrunk after being surrounded by the encapsulant 106. Hence, a post-assembly tightening procedure may be carried out according to FIG. 5. For instance, the inlay 110 may be embodied as an internalized mesh which may be made of a material having a value of the CTE being larger than a value of the CTE of the material of the encapsulant 106. As described above, this manufacturing procedure may involve a hot assembly. It is also possible to treat the package body with a post-mold-shrinkage.

In FIG. 5, a completely embedded compression structure 108 is provided for generating a compression force acting on the encapsulant 106 fully circumferentially surrounding said compression structure 108. As shown by reference sign 128, the described configuration may generate a compression force acting predominantly within a horizontal plane of FIG. 5.

FIG. 6 illustrates a cross-sectional view of a package 100 according to yet another exemplary embodiment. FIG. 6 shows an embodiment with a compressive clip being provided with a spring function. According to FIG. 6, compression clamp 120, which may be embodied in a similar way as described referring to FIG. 4, extends into the carrier 102 and may be fixed there at two ends. The compression structure 108 may hence be configured for applying compressive stress to the encapsulant 106 along two opposing horizontal directions 128 which results from the spring function of the compression clamp 120. Additionally, a compression force may also be applied along a vertical direction 130 as a consequence of the connection of the compression clamp 120 with the carrier 102. The embodiment of FIG. 6 has the advantage that, due to the fixed connection between the clamp type connection structure 108 and the encapsulant 106, there is not only a horizontal compression force due to the spring effect of the clamp, but also a vertical compression force due to the connection between the compression structure 108 and the carrier 102.

FIG. 7 illustrates a cross-sectional view of a package 100 according to yet another exemplary embodiment.

As shown, the compression structure 108 may be embodied as an exterior housing or casing 122 which surrounds part of the encapsulant 106 and thereby applies a compressive force to the encapsulant 106.

For instance, the exterior casing 122 may be a further encapsulant partially encapsulating the encapsulant 106 while exerting compressive stress. Said further encapsulant may for instance be an organic encapsulant.

Additionally or alternatively, the exterior casing 122 may have an interior opening smaller than the volume of the encapsulant 106 so that the encapsulant 106 may be press fit into the opening to thereby apply the compressive stress.

Additionally or alternatively, the exterior casing 122 may be made of a material being shrunk after partially surrounding the encapsulant 106, to thereby create compressive stress.

Additionally or alternatively, the encapsulant 106 and/or the compression structure 108 may comprise filler particles 129 being expanded after surrounding the encapsulant 106 by the casing 122. The expanded filler particles 129 may thereby apply the compressive stress. As shown in a detail 142, the material of the encapsulant 106 and/or the material of the casing 122 may comprise such filler particles 129 which can be expanded by an external trigger, for instance the application of heat or the supply of microwaves. This expansion of the filler particles 129 may form a compression force acting on the encapsulant 106.

Additionally or alternatively, the exterior casing 122 may be made of a material having a negative coefficient of thermal expansion while a material of the encapsulant 106 may have a positive coefficient of thermal expansion. When the temperature increases (for instance during operation of the package 100), the described combination of the CTE values will automatically exert a compressive force to the encapsulant 106, since the encapsulant 106 will expand and the surrounding casing 122 with contract.

As illustrated in FIG. 7 by four arrows and reference sign 132, the compression structure 108 may be configured for applying compressive stress to the encapsulant 106 along four (or more) directions 132 being oriented inwardly and being tilted with respect to each other. Highly advantageously, the embodiment of FIG. 7 generates a compression force acting circumferentially inwardly onto the encapsulant 106. This provides a highly efficient protection against the formation of cracks and against delamination between electronic component 104 and encapsulant 106.

As shown, the embodiment of FIG. 7 may provide an external housing or casing 122 with small filling holes 174, for instance for filling an internalized mesh with a value of the CTE being larger than a value of the CTE of the body. This may be combined advantageously with a hot assembly. It is also possible to carry out a post-mold-shrinkage process applied to the package body.

In the embodiment of FIG. 7, it is for instance possible to apply material of the encapsulant 106 through one or more small openings 174 formed in the casing 122. Thereafter, it may be possible to close the openings 174 with a plug or the like (not shown).

The for instance leadframe- or substrate-type carrier 102 of the package 100 shown in FIG. 7 may be optionally electrically insulated at the bottom side.

FIG. 8 illustrates a cross-sectional view of a package 100 according to yet another exemplary embodiment.

In the shown embodiment, the compression structure 108 comprises or consists of an exterior mold compound, in particular comprising an epoxy resin or a polymer ceramic. Descriptively speaking, it can be possible to over-mold a cement-type encapsulant 106 with a material with higher CTE. Especially, a polymer or a filled polymer may be used for the encapsulant-type compression structure 108.

An encapsulant material of the compression structure 108 may be especially of the groups of epoxy or another mold compound, or polymer ceramics. If the over-mold material is applied at elevated temperature (for instance 175° C. or 200° C.), there will be a compressive strength applied to the cement material as the over-mold material tends to shrink stronger then the cement (higher CTE than cement). The same concept can be applied for modules as well. According to FIG. 8, inorganic encapsulant 106 may thus be overmolded by mold-type encapsulant forming the compression structure 108.

FIG. 9 illustrates a cross-sectional view of a package 100 according to yet another exemplary embodiment.

FIG. 9 shows a power module realization in which cement is applied in a housing to thereby form encapsulant 106. Pressure is applied by pressing a plate, which constitutes a compression structure 108, to the housing for instance by clamps 180, or by screws to put pressure between top plate type compression structure 108 and carrier 102 which is here embodied as a bottom plate (for instance as direct copper bonding carrier, DCB). For instance, the pressure may be applied through the DCB or at the side of the DCB.

Different forms and materials of the top plate are possible for embodying compression structure 108 (for instance concave, flat, convex, with or without holes, with small and large holes, etc.). One or more clamps 180 may be used to press the plate downwardly. Various pins and connectors are shown in FIG. 9 as well, see reference sign 182. Furthermore, a module housing with base plate (for instance of polymer) is illustrated. Wires, cement, and a single or multiple electronic components 104 (for instance dies) may be provided as well.

In general, a compressive force may be applied when the cement is still liquid or when the cement is already solidified. A one directional or a multi directional compressive force (for instance isostatic) may be applied.

In the embodiment of FIG. 9, a compression plate, as compression structure 108, is pressed on top of the encapsulant 106 to apply a compression force in a vertical direction. Also the clamps 180 can provide a contribution to the compression force. Reference numeral 182 denotes electric contacts extending out of the encapsulant 106 of the module type package 100. Said module type package 100 also comprises a surrounding frame 150 in which the multiple electronic components 104 (in particular naked dies) may be inserted. As in FIG. 8, upper main surfaces of the electronic components 104 are connected with the carrier 102 by a respective bond wire 144.

For example, carrier 102 of the module type package 100 of FIG. 9 may be a leadframe or may be a carrier having a central thermally conductive and electrically insulating layer (for instance a ceramic layer) sandwiched on both opposing main surfaces thereof with a respective electrically conductive layer (such as a copper layer).

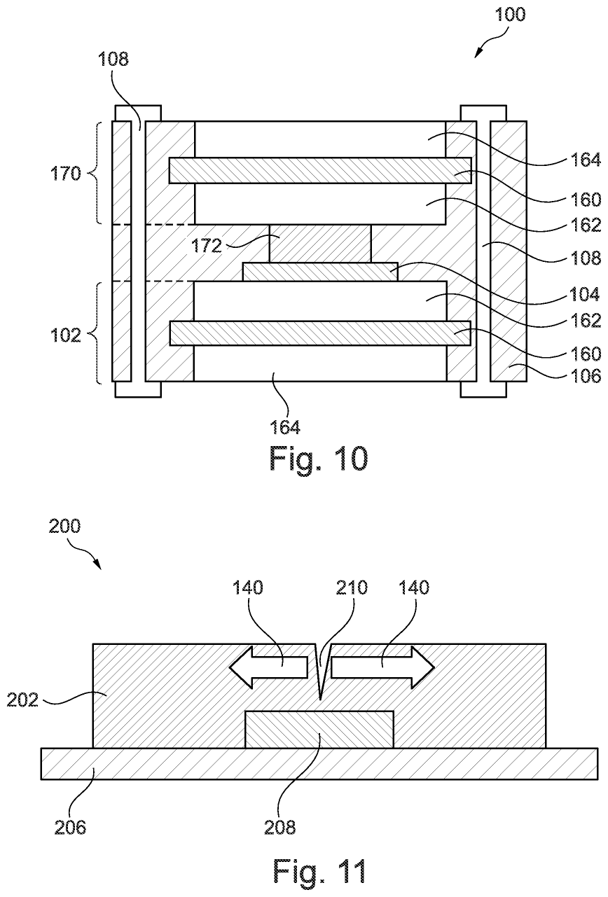

FIG. 10 illustrates a package 100 with double-sided cooling performance according to still another exemplary embodiment.

According to FIG. 10, the electronic component 104 is mounted on a first carrier 102, which is in the shown embodiment a three-layer carrier having a central electrically insulating and thermally conductive layer 160 covered on both opposing main surfaces thereof with a respective electrically conductive layer 162, 164. For instance, the first carrier 102 may be a DCB (direct copper bonding), a DAB (direct aluminium bonding), or AMB substrate. More specifically, the central electrically insulating and thermally conductive layer 160 may be a ceramic layer, and the two electrically conductive layers 162, 164 on the main surfaces of the ceramic layer may for example be copper layers and/or aluminium layers. Moreover, a second carrier 170 may be provided which may be mounted on or above (for instance separated by a spacer 172) an upper main surface of the electronic component 104. The second carrier 170 may be constructed similar or identical as the first carrier 102 (as indicated in FIG. 10 with reference signs 160, 162, 164) or may be constructed in another way (for instance as leadframe). The arrangement composed of the electronic component 104, the first carrier 102 and the second carrier 170 may be encapsulated by the above-described encapsulant 106, for instance made of a ceramic material such as cement. This provides a highly temperature-stable, but brittle material. Additionally, a compression structure 108 is provided as part of the package 100 shown in FIG. 10 which applies compressive stress to the encapsulant 106 and to the electronic component 104 embedded therein. Furthermore, said compressive stress is also applied to the first carrier 102 and the second carrier 170. As a result, not only the formation of cracks in an interior of the encapsulant 106 may be safely prevented thanks to the compression structure 108, but also the interfaces between electronic component 104, first carrier 102, second carrier 170 and encapsulant 106 may be compressed so as to efficiently suppress highly undesired delamination. At the same time, the presence of the first carrier 102 and the second carrier 170 allows for a double-sided cooling of the electronic component 104, which may for instance be a power semiconductor chip. Hence, the enormous amount of heat which may be generated by the encapsulated electronic component 104 during operation of the package 100 may be removed out of the package 100 via two opposing main surfaces of the package 100, i.e. in a specifically efficient way. This also contributes to an improvement of the mechanical reliability of the package 100.

FIG. 11 illustrates a cross-sectional view of a conventional package 200 with brittle encapsulant 202 schematically illustrating tension caused breakage.

FIG. 11 shows conventional package 200 with a carrier 206 on which an electronic component 208 is mounted. An inorganic encapsulant 202 encapsulates the electronic component 208. Due to the brittle character of the inorganic encapsulant 202, it is prone to the formation of one or more cracks 210 in the presence of tension stress, see reference sign 140.

In contrast to such conventional approaches, exemplary embodiments avoid the described undesired phenomenon by the provision of a (preferably permanent) compression force, for instance applied by a compression structure 108.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, which comprises:
a carrier;
an electronic component mounted on the carrier;
an encapsulant encapsulating at least part of the carrier and at least part of the electronic component;
a compression structure configured for applying compressive stress to at least part of the encapsulant; and
wherein a material of the compression structure has a higher coefficient of thermal expansion than the encapsulant.

2. The package according to claim 1, wherein the encapsulant is an inorganic encapsulant.

3. The package according to claim 1, wherein the encapsulant comprises or consists of at least one of the group consisting of a ceramic, in particular cement, and a glass.

4. The package according to claim 1, wherein the encapsulant is not an organic mold compound, in particular not an epoxy based mold compound.

5. The package according to claim 1, wherein the compression structure comprises a compressive inlay which is at least partially arranged in an interior of the encapsulant and applies a compression force to the encapsulant, wherein in particular the compressive inlay is a grid.

6. The package according to claim 1, wherein the compression structure comprises or consists of a material having a larger coefficient of thermal expansion than a material of the encapsulant, wherein in particular the compression structure is connected with the encapsulant in a heated condition.

7. The package according to claim 1, wherein the compression structure comprises at least one fastening element fastened on the encapsulant to thereby apply compressive stress to the encapsulant.

8. The package according to claim 7, wherein the compression structure comprises a connection body having an encapsulated portion in the encapsulant and a non-encapsulated portion exposed with respect to the encapsulant, and wherein the at least one fastening element is fastened on the non-encapsulated portion.

9. The package according to claim 1, wherein the compression structure comprises a compression clamp, in particular a compressive clip, engaging at least part of the encapsulant with a compression force, wherein in particular the compression clamp extends into the carrier.

10. The package according to claim 1, wherein the compression structure is made of a material being shrunk after being at least partially surrounded by the encapsulant and/or after at least partially surrounding the encapsulant.

11. The package according to claim 1, wherein the compression structure comprises or consists of an exterior casing at least partially surrounding the encapsulant and applying compressive stress to the encapsulant.

12. The package according to claim 11, comprising at least one of the following features:
wherein the exterior casing is a further encapsulant, in particular a mold compound, at least partially encapsulating the encapsulant;
wherein the exterior casing has an opening smaller than a volume of the encapsulant being press fit into the opening;
wherein the exterior casing is made of a material being shrunk after at least partially surrounding the encapsulant;
wherein the encapsulant and/or the casing comprises filler particles being expanded after at least partially surrounding the encapsulant by the casing to thereby apply the compressive stress to the encapsulant;
wherein the exterior casing is made of a material having a higher coefficient of thermal expansion than the encapsulant.

13. The package according to claim 1, wherein the compression structure comprises or consists of a mold compound, in particular comprising an epoxy resin or a polymer ceramic.

14. The package according to claim 1, wherein the compression structure is configured for applying compressive stress to the encapsulant at least along two opposing, in particular horizontal, directions, at least along a vertical direction, and/or at least along four directions being oriented towards an interior of the package.

15. The package according to claim 1, comprising a further carrier, wherein the electronic component is arranged between the carrier and the further carrier in such a manner that heat generated by the electronic component is removable via the carrier and via the further carrier.

16. The package according to claim 1, configured as a module, in particular comprising a plurality of encapsulated electronic components and/or comprising an exterior frame.

17. The package according to claim 1, wherein the compression structure comprises an exterior compression body, in particular an exterior compression plate, pressed onto the encapsulant.

18. The package according to claim 1, wherein the compression structure is configured for applying a compressive stress of at least 100 N/m², in particular at least 1000 N/m², more particularly at least 10000 N/m², to the encapsulant.

19. A method of manufacturing a package, wherein the method comprises:
mounting an electronic component on a carrier;
encapsulating at least part of the carrier and at least part of the electronic component by an encapsulant;
applying permanent compressive stress to at least part of the encapsulant, in particular for counteracting tension stress; and
connecting a compression structure, made of a material having a higher coefficient of thermal expansion than a material of encapsulant, with the encapsulant in a heated condition so that the compression structure applies compressive stress to the encapsulant at an operation temperature below the headed condition.

20. The method according to claim 19, comprising at least one of the following features:
wherein the method comprises at least partially surrounding the encapsulant with a casing type compression structure having a value of the coefficient of thermal expansion being larger than a value of the coefficient of thermal expansion of the encapsulant, wherein the method further comprises surrounding the encapsulant by the casing at a temperature above operation temperature of the package and subsequently operating the package at the lower operation temperature;
wherein the method comprises at least partially surrounding the encapsulant with a casing type compression structure having a value of the coefficient of thermal expansion being smaller than a value of the coefficient of thermal expansion of the encapsulant, wherein the method further comprises surrounding the encapsulant by the casing at a temperature below operation temperature of the package and subsequently operating the package at the higher operation temperature;
wherein the method comprises fastening a fastening element on an exterior of the encapsulant after completing the encapsulating to thereby apply the compressive stress to the encapsulant;
wherein the method comprises press fitting the encapsulant into an opening of an exterior casing to thereby apply the compressive stress to the encapsulant;
wherein the method comprises surrounding the encapsulant by an exterior casing, and subsequently shrinking a material of the exterior casing to thereby apply the compressive stress to the encapsulant;
wherein the method comprises surrounding the encapsulant by an exterior casing, and subsequently expanding filler particles of the encapsulant and/or the casing to thereby apply the compressive stress to the encapsulant;
wherein the method comprises applying a permanent compressive stress of at least 100 N/m², in particular at least 1000 N/m², more particularly at least 10000 N/m², to the encapsulant;
wherein the method comprises applying a compressive stress exceeding a tension stress by at least 10⁻³ N/m², in particular by at least 1 N/m², more particularly by at least 100 N/m².
